(19) United States
(12) Patent Application Publication
(10) Pub. No.: US 2023/0064997 A1
(43) Pub. Date: Mar. 2, 2023

(54) EAS DEVICE WITH TAMPER DETECTION

(71) Applicant: Xiao Hui Yang, Saratoga, CA (US)

(72) Inventor: Xiao Hui Yang, Saratoga, CA (US)

(21) Appl. No.: 17/899,810

(22) Filed: Aug. 31, 2022

Related U.S. Application Data
(60) Provisional application No. 63/238,942, filed on Aug. 31, 2021.

(51) Int. Cl. G08B 13/24; H05K 5/02

(52) U.S. Cl. CPC G08B 13/2434; H05K 5/0208; H05K 5/0217

(57) ABSTRACT

An electronic article surveillance (EAS) device has a body and a mount for attaching to a protected item. The body houses electronic elements and the mount adhesively attaches to the protected item. A stem with tabs extends upward from the mount. The body has an aperture for receiving the stem. The stem tabs and body interlock to keep the body attached to the item. A actuator from a switch in the body extends through the stem toward the item. A shaft and a separate floater element initially associated with the mount interpose between the plunger and the item. When the device is attached to an item and armed, tampering with the device dislodges the floater and allows the shaft and actuator of the switch to extend. This changes the state of the mount switch and the electronics in the body determine an alarm condition and issue an alarm.

### CROSS REFERENCE TO RELATED APPLICATIONS

This application is a utility application which claims priority to U.S. Provisional Application 63/238,942, filed on Aug. 31, 2022. The entire disclosures contained in U.S. Provisional Application 63/238,942 including the attachments thereto, are incorporated herein by reference.

### FIELD OF THE INVENTION

This invention relates to the tracking of goods. More specifically, this invention relates to the tracking of goods by an electronic article surveillance (EAS) device adhesively attachable to an item and having a configuration easily destabilized by tampering which provides detection of tampering and/or theft.

### BACKGROUND OF THE INVENTION

Theft is frequently a problem in retail stores as well as in other environments. In some environments, the focus is on the desire to track items. To address these issues, electronic article surveillance (EAS) systems are installed. Generally, in EAS systems, electronic tags, labels, or similarly titled electronic devices are placed on items to be protected, or monitored. These EAS tags, or devices, are capable of generating a signal to reply back to the broader EAS system. The broader EAS system creates interrogation fields which stimulate the EAS devices to produce reply signals in response to the interrogation fields. These responding signals from the EAS devices, indicate that an EAS device, and the item to which it is attached, are in an interrogation field.

These interrogation fields are frequently set up at exits or entries to an area that is being monitored or protected. Frequently, the antennas that are used to generate the interrogation fields and to monitor for device signals are housed within pedestals that are placed to each side of an exit. However, these antennas and their controlling electronics can be positioned overhead or within the floor in the area close to the exit.

The controlling electronics for these antennas generate a signal which is transmitted by the antennas and creates the interrogation field. This field energizes or stimulates devices that are passing through the interrogation field, or zone. The devices then produce a signal in response to the interrogation field. This signal from the devices may be created by the energy of the field itself, or the devices may have on board power supplies and electronics that reply to the interrogation field. The interrogation field is cycled for periods of transmission and monitoring. The interrogation field initially cycles and broadcast out into the zone being monitored and then the interrogation field is stopped. The antennas of the EAS system then monitor for a device signal. If a device signal is detected, it is assumed that the device is improperly in the zone being monitored by the interrogation field, and the EAS system determines that an alarm condition is in effect. The EAS system can then generate an alarm, either an optical alarm such as flashing lights, an audible alarm such as bells, etc., or a system alarm that is broadcast to operator stations.

EAS tags, or devices, are attached to items by various methods. The method used depends on the type of item being protected and determines the shape of the EAS device. As one example, EAS devices for clothing frequently employ a tack to maintain the EAS device on the article of clothing. Other applications use different methods which leads to EAS devices having different physical characteristics. In some cases, EAS devices employ an adhesive to maintain the device on the item, and these may also employ a switch to monitor the continued attachment of the EAS device on the item. If the EAS device is removed from an item, the state of the switch is changed. Logic within the EAS device interprets the state change as meaning that the device has been removed, determines an alarm condition exists, and transmits an alarm. The alarm may an audible sound, a transmission to other system elements, or both.

One method a thief may employ to defeat an EAS device with such a switch is to maintain the state of the switch while removing the EAS device. For example, if the switch is actuated by an actuator compressed when the EAS device is attached to the item, the thief will maintain the compressed state of the actuator while removing the EAS device. This may be accomplished by inserting a thin element between the item and the EAS device. The thin element and the EAS device are then removed together and the switch and alarm of the EAS device are defeated.

### RELEVANT ART

U.S. Pat. Application Publication 2015/0302711 A1 by Yang is for “EAS DEVICE HAVING INTERCHANGEABLE CONTOURED BASE”. In Yang ‘711, an electronic article surveillance device attaches to an object to be protected. The EAS device has a base, or mount, and a housing which contains EAS electronics. The housing and base are separate but have elements which act together to attach the housing to the base. The base attaches to the object and has a surface contoured to fit the contour of the object to be protected. The base, or mount, may be attached to the object by an adhesive element. Multiple interchangeable bases having differently countered surfaces allow a housing to be attached to different objects having different contours.

U.S. Pats. 8,305,219 and 8,368,542 by Yang are for “EAS tag using tape with conductive element”. In Yang '219 and '542, an electronic article surveillance apparatus for monitoring large objects is comprised of a base, at least one segment of tape, and an electronics housing. The segment of tape has at least one electrically conductive element running the length of the tape. The base rests on an object to be monitored, and the housing releasably latches onto the base, while each tape segment wraps around the object with each end of tape segment being fixed between the base and housing. Electronics within the housing complete a circuit through each tape segment and monitors the tape segments for electrical continuity. If electrical continuity is lost, either by cutting a tape segment, or unauthorized unlatching of the housing, an alarm can be sounded by the electronics within the housing. The electronic housing may be disarmed by a remote device and unlatched from the base. Both base and tape segments may have adhesive elements.

U.S. Pat. 8,373,565 by Yang is for “Security apparatus with conductive ribbons”. In Yang '565, an electronic article surveillance (EAS) security apparatus is comprised of a housing, base plate, ribbon pad, and electrically conductive ribbons. In one embodiment, the ribbons are pre-attached to the ribbon pad and extend from the ribbon pad. The ribbon pad and base plate are installed on opposite sides of an object to be protected. The ribbons are extended around the object, and their extended ends attached to the base plate. The housing has electrical contacts and encloses electronics. It is attached to the base plate in such a way that the electrical contacts complete circuits through the ribbons. The electronics in the housing monitors the ribbons to detect unauthorized removal of the apparatus. A switch on the bottom of the housing detects that the housing is attached to a plate and object. The apparatus has a locking mechanism to maintain the housing and plate together, which can be released by application of a magnet.

U.S. Pat. 10,311,691 B2 by Yang is for “Anti-theft tag with attaching panel”. In Yang '691, an electronic article surveillance (EAS) device has a housing containing EAS electronics and a panel extending from the housing. An adhesive element on the panel provides a means of attaching the EAS device to an object to be monitored. The EAS device has a switch to detect when the EAS device is mounted to an object. The electronics within the housing monitor the switch. The switch may be associated with, or mounted in, the panel. The panel may be hinged to the housing. The panel may fold flat to the housing when not in use, and the switch will disconnect any power source to conserve energy when the panel is closed. The EAS electronics can communicate with external devices and an external EAS system which may include cloud functionality.

U.S. Pat. 9,997,037 B2 by Yang is for “Anti-theft tag for electronic device charging port”. In Yang '037, an electronic article surveillance (EAS) device has a plug configured to fit a port of a portable electronic device. In some embodiments, the port used in the portable electronic device is a charging port. The EAS device may have an additional attaching mechanism to maintain the EAS device attached to a portable electronic device. In one embodiment, the additional attaching mechanism is a panel with an adhesive element. The EAS device may have a switch that changes state when the plug is inserted into the port. Electronics within the EAS device may monitor the switch and plug to detect attachment of the EAS device. The EAS device may also have a charging port in electrical continuity with the plug so that the electronic device can be charge with the EAS device in place.

### SUMMARY FOR EMBODIMENTS OF THE INVENTION

An electronic article surveillance (EAS) antitheft device has a body and a mount for attaching the body to a protected item. The body houses electronic elements for monitoring the state of the device, for communicating with external devices in a greater antitheft or tracking system, and for executing logic associated with those functions. The mount has an adhesive element on its contact surface and adhesively attaches to the protected item. The body then attaches to the mount.

In some embodiments of the EAS device, the mount has a base, and it is on that base where the adhesive is located. The base may be sufficiently thin and pliable such that the base can conform to curved surfaces on an item. In some embodiments, the base may have slots in it to provide further flexibility so that the base may more easily adhesively attach to curved surfaces.

The base has a stem extending up from it. The stem has tabs extending laterally at its end. The body has a coupler aperture for receiving the stem and that aperture has notches in it to accommodate the tabs. After the body is placed on the stem, turning the body couples the body and the mount to each. The body may house a locking mechanism, such as a slide, that may be manually moved to lock the body in place on the mount. The body may house a lock switch that detects the position of the locking mechanism and communicates the position to the other electronics in the body. The electronics of the body may arm the EAS device as a result of receiving the signal from the lock switch.

A mount switch within the body aligns with the coupler aperture in the body. The mount has a mount aperture that passes through the base and the stem of the mount. An actuator from the mount switch aligns with the mount aperture in the stem when the body is assembled with the mount. Previous to its installation, the mount has a tamper detector in the mount aperture. The tamper detector has a shaft and a floater element temporarily connected to the base at the mount aperture on the opposite surface from the stem. When the body is attached to the mount, the actuator moves the shaft which then detaches the floater element. The floater element is trapped between the shaft and the surface of the item in a precarious equilibrium. If an attempt is made to remove the device, the floater element is easily displaced, which allows the shaft of the tamper detector and switch actuator to shift. This is detected by the mount switch which communicates to the other electronics housed in the body of the device. The logic components of the electronics determine an alarm condition, and the communication components of the electronics issue an alarm.

The electronics within the body are capable of communicating with external elements of a greater security system. Theses communication elements can receive signals as a final arming step for installation of the EAS device or to disarm the device, so that it may be removed without issuing an alarm. The communication can with contact or wireless communication. An authorized person can disarm the device.

### BRIEF DESCRIPTION OF THE DRAWINGS

Additional utility and features of the invention will become more fully apparent to those skilled in the art by reference to the following drawings, which illustrate some of the primary features of preferred embodiments.

FIG. 1 is an upper perspective view of an embodiment of an EAS device having a body and a mount for the body.

FIG. 2 is a side view of an embodiment of an EAS device having a body and a mount for the body.

FIG. 3 is a top perspective view of an embodiment of a body of an EAS device.

FIG. 4 is a top perspective view of an embodiment of a body of an EAS device with the top removed from the device body to show a mount stem inserted.

FIG. 5 is a top perspective view of an embodiment of a body of an EAS device with the top removed from the device body, showing a mount stem turned after insertion.

FIG. 6 is a top perspective view of an embodiment of a body of an EAS device with the top removed from the device body, showing a slide blocking the mount stem.

FIG. 7 is a bottom perspective view of an embodiment of a mount of an EAS device, showing the mount stem.

FIG. 8 is a perspective view of an embodiment of a mount of an EAS device, showing the mount contact surface on the bottom.

FIG. 9 is a perspective view of an embodiment of a mount of an EAS device, showing a floater element initially fixed to the mount.

FIG. 10 is a side perspective view of an embodiment of a mount of an EAS device, showing a floater element initially fixed to the mount.

FIG. 11 is a perspective view of an embodiment of a mount of an EAS device, showing a floater element and shaft of a tamper detector extended from the mount.

FIG. 12 is a side perspective view of an embodiment of a mount of an EAS device, showing a floater element and shaft extended from the mount.

FIG. 13 is a perspective view of an embodiment of a mount of an EAS device, showing a floater element displaced.

FIG. 14 is a side perspective view of an embodiment of a mount of an EAS device, showing a floater element displaced.

FIG. 15 is an exploded perspective view of an embodiment of an EAS device having a body and a mount for the body.

FIG. 16 is an exploded side perspective view of an embodiment of an EAS device having a body and a mount for the body.

FIG. 17 is a bottom perspective view of an embodiment of an EAS device having a body and a mount for the body with the body exploded.

FIG. 18 is a side view of an embodiment of an EAS device having a body and a mount for the body with the mount applied to an item with a curved surface.

### DETAILED DESCRIPTION OF EMBODIMENTS

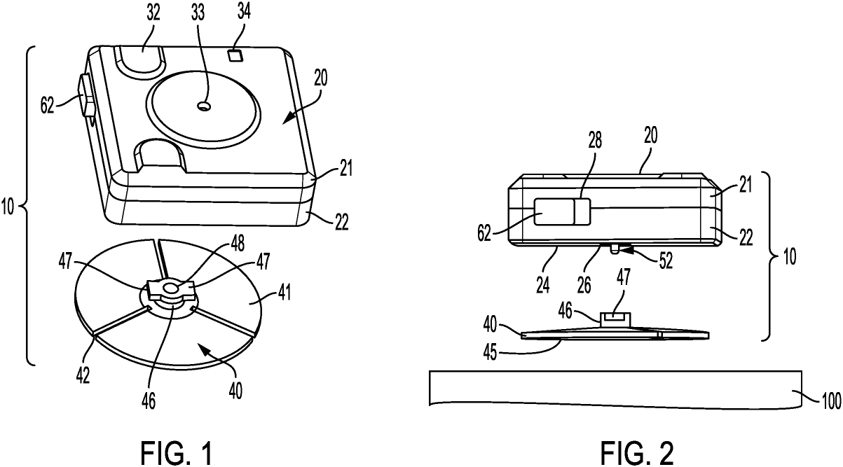

FIG. 1 is an upper perspective view of an embodiment of an EAS device 10 having body 20 and mount 40 for body 20. Mount 40 is comprised of base 41 and stem 46. In the embodiment of FIG. 1, base 41 is disc shaped and sufficiently thin to be flexible. Slots 42 in base 41 divide base 41 into multiple sections 43. Among other benefits, this provides additional flexibility to base 41. Stem 46 extends from base 41. Stem 46 has tabs 47 extending from it and mount aperture 48 through it. Mount aperture 48 extends through the length of stem 46 and base 41, i.e. through mount 40. In the embodiment shown in FIG. 1, stem 46 is centrally located on base 41.

FIG. 2 is a side view of an embodiment of an EAS device 10 having body 20 and mount 40 for body 20. Actuator 52 of a switch located within body 20 extends beyond bottom surface 24 of body 20. Actuator 52 aligns with stem 46 of mount 40 to insert into mount aperture 48 of stem 46. FIG. 2 shows item 100 beneath mount 40 representing an item to be protected by application of an embodiment of EAS device 10.

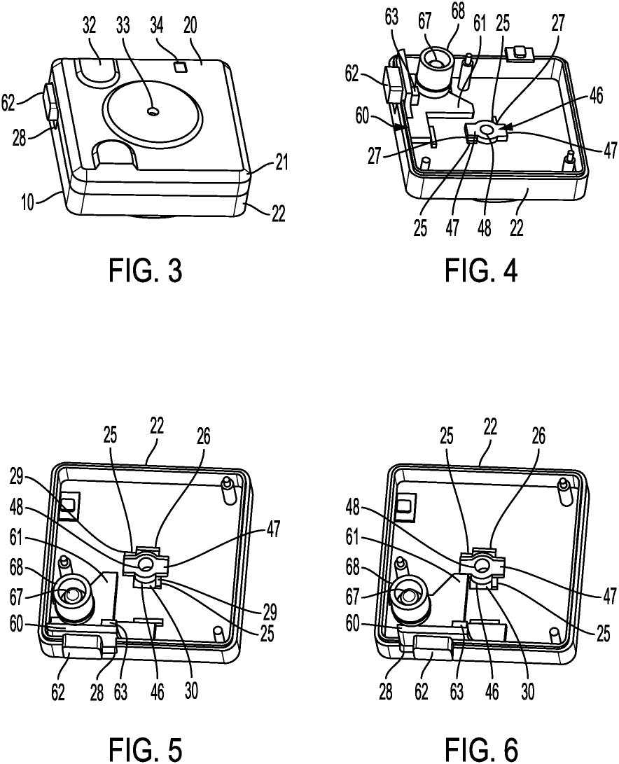

FIG. 3 is a top perspective view of an embodiment of body 20 of an EAS device 10 comprised of top shell 21 and bottom shell 22. FIG. 4 is a top perspective view of an embodiment of body 20 of an EAS device 10 with top shell 21 removed, showing the inside of bottom shell 22. Stem 46 is inserted into bottom shell 22 through coupler aperture 26 (not apparent in FIG. 4). Stem 46 is in an initial orientation with tabs 47 contacting pegs 25 of bottom shell 22 on first edges 27 of pegs 25. Slide 60 in bottom shell 22 is in an initial position with locking arm 61 of slide 60 spaced away from stem 46 and tabs 47. Pin cup 68 and blocking pin 67 are positioned over slide 60. Button 62 of slide 60 extends through button aperture 28 of body 20. Button 62 may also be seen in FIGS. 1-3 and other figures.

FIG. 5 is a top perspective view of an embodiment of a body 20 of an EAS device 10 with top shell 21 removed from device body 20, showing mount stem 46 rotated to an interlocking position with tabs 47 contacting second edges 29 of pegs 25. Stem 46 may not be withdrawn from coupler aperture 26 when body 20 and stem 46 are in this relative orientation. Slide 60 is still in an initial position with locking arm 61 still spaced away from stem 46 and tabs 47. In FIG. 5, the shape of coupler aperture 26 may be more clearly seen. Coupler aperture 26 has tab notches 30 in it which require a particular orientation of stem 46 and tabs 47 to allow insertion and withdrawal of stem 46.

FIG. 6 is a top perspective view of an embodiment of a body 20 of an EAS device 10 with top shell 21 removed from device body 10, showing slide 60 moved to a blocking position. Locking arm 61 is in contact with mount stem 46 and one of tabs 47, preventing stem 46 from rotating. With stem 46 prevented from rotating, the relative angular orientation of body 20 and mount 40 cannot be changed to bring tabs 47 into alignment with tab notches 30 in coupler aperture 26. This prevents body 20 from being separated from mount 40.

When slide 60 is moved to engage locking arm 61 with stem 46 and tabs 47, a spring moves blocking pin 67 in pin cup 68 to a blocking position with respect to slide 60. Blocking pin 67 then keeps slide 60 in place until blocking pin 67 is withdrawn back into pin cup 68. More will be discussed below with respect to slide 60 and blocking pin 67.

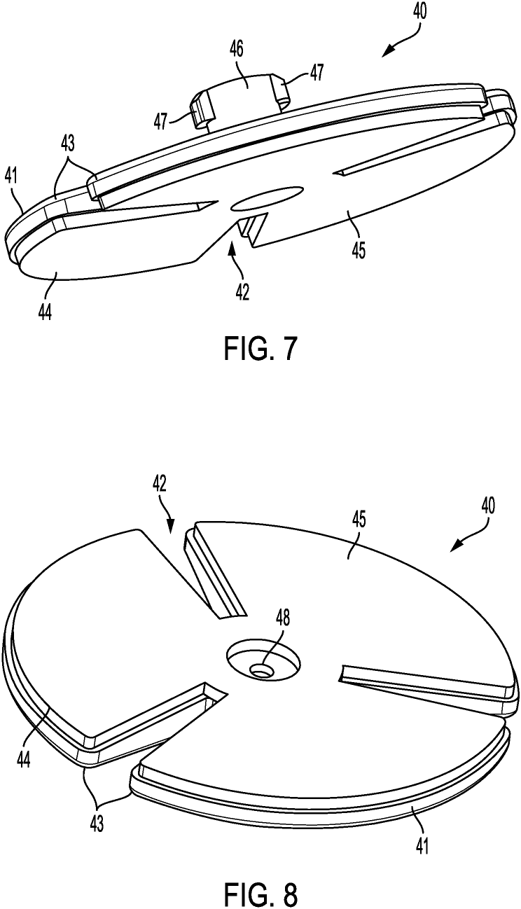

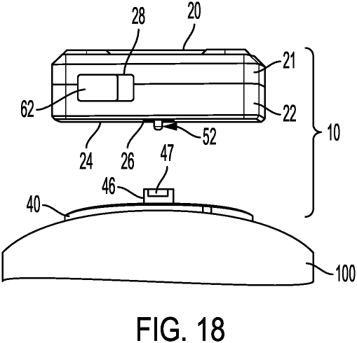

FIG. 7 is a bottom perspective view of an embodiment of mount 40 of EAS device 10, showing mount stem 46, tabs 47, and base 41. Additionally, FIG. 7 shows adhesive element 44. Adhesive element 44 may be an adhesive applied directly to base 41, or adhesive element 44 may be an adhesive pad having adhesive on both sides. Adhesive element 44 attaches mount 40 to an item being protected. Base 41 is flexible enough to adapt to curved surfaces on items. FIG. 18 shows base 41 of mount 40 applied to item 100 having a curved surface.

Referring now to FIGS. 1-7, once mount 40 is attached to an item, body 20 of EAS device 10 is attached to mount 40 by inserting stem 46 into coupler aperture 26 in body 20 and turning body 20 until pegs 25 contact tabs 47. Moving slide 60 until locking arm 61 engages stem 46 and tabs 47 prevents turning motion between body 20 and mount 40. Blocking pin 67 then moves into its blocking position to lock body 20 to mount 40 until blocking pin 67 is withdrawn into pin cup 68. The withdrawal of blocking pin 67 allows slide 60 to be moved away from stem 46, which in turn allows rotation of body 20 on stem 46 to align tabs 47 with tab notches 30 in coupler aperture 26. With tabs 47 aligned with tab notches 30, body 20 may be removed from mount 40. Before use, mount 40 may have a covering over adhesive element 44 which is removed to attach mount 40 to an item.

FIG. 8 is a perspective view of an embodiment of mount 40 of an EAS device 10, showing mount contact surface 45 on the bottom of mount 40. Mount aperture 48 in mount 40 passes through stem 46. Referring to FIG. 2, when body 20 is placed on mount 40, actuator 52 inserts into stem 46. In at least one embodiment of EAS device 10, actuator 52 is not long enough to extend all the way through mount 40.

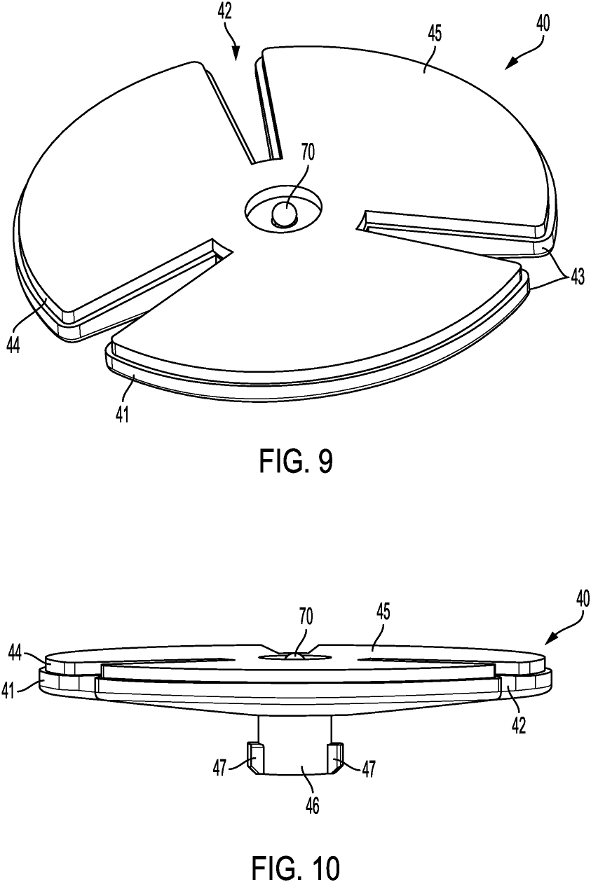

FIGS. 9 and 10 are perspective views of an embodiment of a mount 40 of EAS device 10 showing floater element 70 initially fixed to the mount 40. In FIG. 9, it may be seen that floater element 70 is seated in mount aperture 48. In FIG. 10, it may be seen that in its initial position, the top of floater element 70 is essentially flush with contact surface 45 of adhesive element 44.

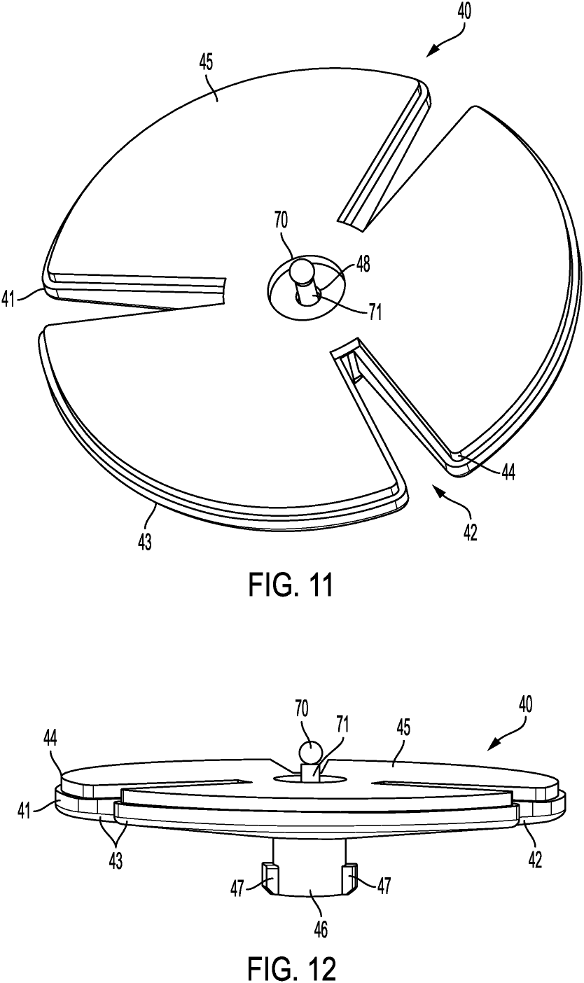

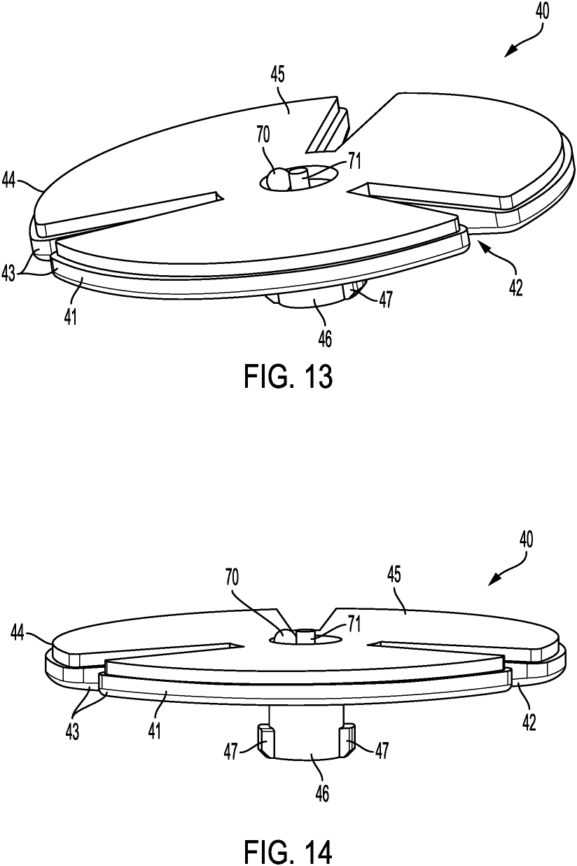

FIGS. 11 and 12 are perspective views of an embodiment of mount 40 of EAS device 10 showing floater element 70 displaced and extended from mount aperture 48 by shaft 71. In the embodiment of FIGS. 11 and 12, shaft 71 is initially located within mount aperture 48. When body 20 is placed on stem 46 of mount 40, actuator 52 displaces shaft 71 which extends and detaches floater element 70 from mount 40 at mount aperture 48. Floater element 70 is not fixed on shaft 71. When mount 40 is attached to an item and body 20 is joined to mount 40, shaft 71 detaches floater element 70, and the item assists in maintaining floater element 70 in place at the end of shaft 71. If an attempt is made to defeat the switch by sliding a thin object between the item and mount 40, floater element 70 will be displaced, allowing shaft 71 to shift. This allows actuator 52 to extend and changes the state of the switch. FIGS. 13 and 14 are perspective views of an embodiment of a mount 40 of EAS device 10, showing a floater element 70 displaced and shaft 71 extended.

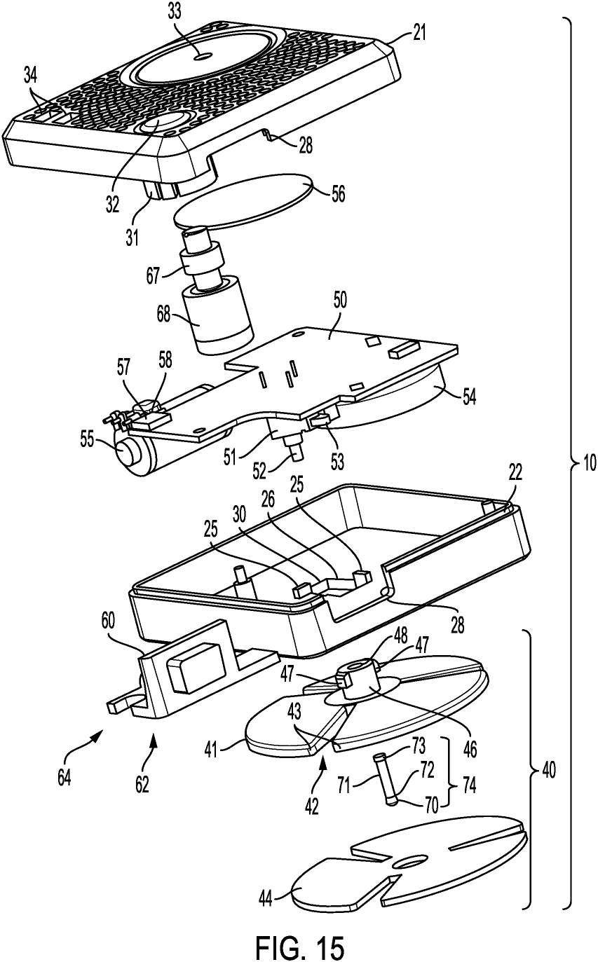

FIG. 15 is an exploded perspective view of an embodiment of an EAS device 10 having body 20 and mount 40 for the body 20. Circuit board 50 carries most of the internal electronic elements of EAS device 10. These electronic elements include: mount switch 51; lock switch 53; battery 54; passive EAS element 55; sound generator 56; a programmable chip (not shown in FIG. 15); and light emitting diodes 57 (LED), and/or other wireless communication elements (also not shown in FIG. 15). Some embodiments of EAS device 10 may have additional elements such as motion sensor chips.

Mount switch 51 aligns with coupler aperture 26. When body 20 is assembled to mount 40, actuator 52 of mount switch 51 aligns with mount aperture 48 in stem 46. When body 20 is assembled to mount 40, actuator 52 has sufficient length and stiffness to contact and move shaft 71. Shaft 71 in turn displaces floater element 70 from its initial seat on mount aperture 48. As discussed above, when mount 40 is attached to an item and body 20 is connected to mount 40, shaft 71 displaces floater element 70, and floater element 70 is then maintained between shaft 71 and the item. If EAS device 10 is tampered with, such as an attempt to slide a thin device between device 10 and the item, floater element 70 is displaced, shaft 71 and actuator 52 shift, and mount switch 51 has its state changed. The electronics of EAS device 10 detect this and determine that an alarm state is present. Audible and wireless alarm signals are then generated.

Lock switch 53 on circuit board 50 signals the position of slide 60, which acts as the locking mechanism in this embodiment. Referring to FIG. 4, switch peg 63 on slide 60 is positioned to contact lock switch 53. When slide 60 is moved from its initial position to engage locking arm 61 with stem 46 and tabs 47 to lock body 20 and stem 46 from rotation, lock switch 53 has its state changed and this provides a signal to the logic components of EAS device 10. When mount switch 51 indicates that actuator 52 is compressed, the combined signals indicate that EAS device 10 is attached to an item. In at least some embodiments, this places EAS device 10 in an armed state. Once EAS device 10 is armed, if tampering displaces floater element 70 and allows actuator 52 of mount switch 51 to extend, an alarm condition will be determined by the logic elements of EAS device 10 which will then issue an alarm. Some embodiments of EAS device 10 may have an additional step of receiving a signal from an external device to complete the arming of EAS device 10. This may be effected through the wireless communication elements of EAS device 10 such as through optical or radio communication.

In FIG. 15, tamper detector 74 is shown fully removed from mount 40. In the embodiment of FIG. 15, tamper detector 74 is comprised of shaft 71 with floater 70. Shaft 71 has a first end 73 and a second end 72. First end 73 has a cap on it. When shaft 71 is inserted into mount aperture 48 from the stem 46 side of mount 40, capped first end 73 keeps shaft 71 from passing all of the way through mount aperture 48 and falling out of mount 40.

Cylinder 31 on top shell 21 of body 20 retains pin cup 68 in position. Pin cup 68 contains blocking pin 67 and spring 69. In the initial uninstalled configuration of EAS device 10, slide 60 holds blocking pin 67 up in pin cup 68 with spring 69 compressed. When slide 60 is shifted to engage locking arm 61 with stem 46 and tabs 47, spring 69 moves blocking pin 67 into pin notch 64 on slide 60. This locks slide 60 into engagement with stem 46 and tabs 47. Locking pin 67 is at least partially made of a magnetically attractable material. To allow slide 60 to be moved back to an initial unengaged position, a magnet is applied to body 20 to withdraw locking pin 67 from pin notch 64. Dome 32 on top shell 21 of body 20 provides a visual cue as to where to apply a magnet.

Sound generator 56 is positioned beneath sound aperture 33 in top shell 21. Sound generator 56 can communicate audible alarms as well as other signals. For example, sound generator 56 may communicate confirmation that EAS device 10 is armed or disarmed.

LED 57 and optical sensor 58 are positioned beneath respective optical windows 34 in top shell 21. LED 57 and optical sensor 58 enable wireless optical communication with EAS device 10. Optical sensor 58 may receive optical signals such as infra-red signals. LED 57 may generate signals for optical receivers on external devices, or can flash to communicate the device status. For example, LED 57 may flash to confirm EAS device 10 is armed.

In FIG. 15, adhesive element 44 is shown separated from base 41 of mount 40. However, adhesive element 44 may more likely be pre-applied to base 41. Pre-application of adhesive element 44 along with preassembly of shaft 71 and floater element 70 with mount 40 produces a unit ready to be applied to an item.

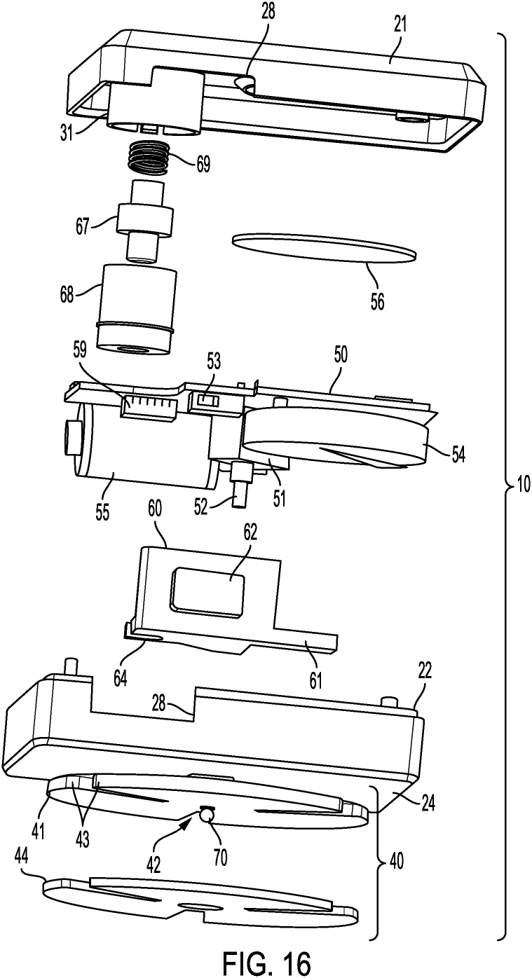

FIG. 16 is an exploded side perspective view of an embodiment of EAS device 10 having body 20 and mount 40 for the body 20. In FIG. 16, the alignment of actuator 52 of mount switch 51 with floater element 70 (and shaft 71) may be seen. Floater element 70 is seated in mount aperture 48 of mount 40. In FIG. 16, passive EAS element 55 is of the type having a ferrite core and conductive coil wrapped around the core. However, other passive EAS elements could be used.

Spring 69 is positioned above blocking pin 67 and fits around the top portion of blocking pin 67 when body 20 is assembled. Spring 69 provides the bias for blocking pin 67 to move to a blocking position when slide 60 is moved to lock body 20 to mount 40. For blocking pin 67 to be withdrawn into cup 68 and cylinder 31, a magnet is applied to dome 32 of body 20 The magnet must be sufficiently strung to overcome spring 69.

Programmable chip 59 on circuit board 50 provides the logic, storage, and communication capabilities of EAS device 10. Programmable chip 59 monitors the status of mount switch 51 and lock switch 53 to determine whether EAS device 10 is installed and armed. Programmable chip 59 may provide radio frequency wireless communication or may communicate wirelessly via LED 57 and optical sensor 58. Additionally, programmable chip 59 may drive sound generator 56 to generate audible sounds. External devices may communicate with ant-theft device 10 as a final arming step after EAS device 10 is installed. When programmable chip 59 determines an alarm condition exists, it can generate various alarms, such as an audible alarm, or wireless alarms transmitted to external devices and the larger EAS systems as a whole.

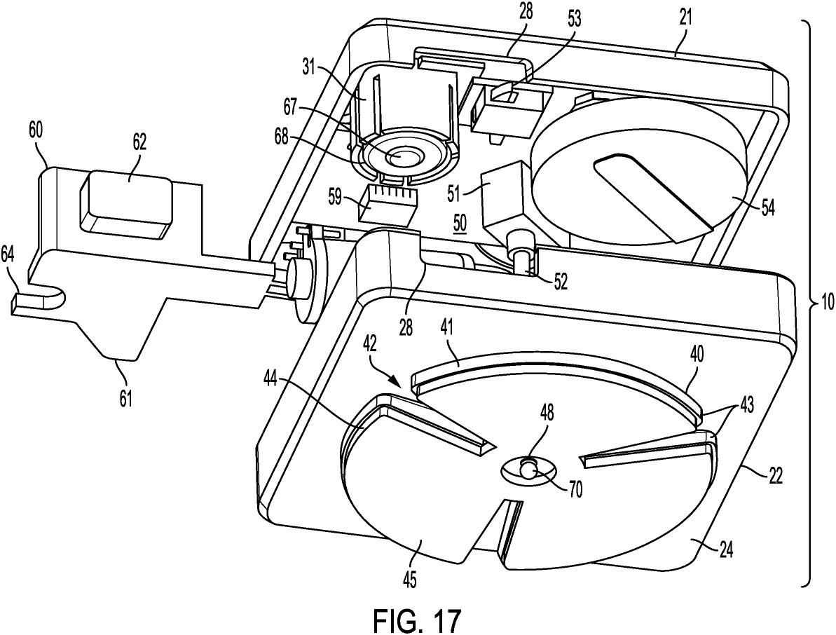

FIG. 17 is a bottom perspective view of an embodiment of EAS device 10 having body 20 and mount 40 for the body 20 with body 20 exploded. In FIG. 17, blocking pin 67, pin cup 68, and spring 69 are shown assembled and in position within cylinder 31 of top shell 21. As discussed above, programmable chip 59 on circuit board 50 provides the logic, storage, and communication capabilities of EAS device 10. Pin notch 64 in slide 60 is well visible in FIG. 17. Adhesive element 44 is in position on mount 40. Floater element 70 is displaced slightly from mount 40 and mount aperture 48 may be seen behind floater element 70.

In FIGS. 9-17, floater element 70 is depicted as a spherical element. However, any shape that provided some level of stability when EAS device 10 is installed on an item may be used. For examples, floater element 70 may have the shape of a disc, cylinder, prism, frustum, etc. Additionally, mount aperture 48 may have a opening perimeter adapted to provide an appropriate seat for a given shape of floater element 70.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the invention be regarded as including such equivalent constructions.

I claim:

1. An electronic article surveillance (EAS) device comprising:
a body housing electronics, the body having a bottom with a first coupler and a switch aperture through the bottom, and the electronics comprising a mount switch aligned with the switch aperture;
a mount having a base and a second coupler, the base having a contact surface and the second coupler being opposite of the contact surface, the contact surface being adhesive, the first coupler of the body and the second coupler of the mount being complementarily configured to allow the body to be coupled to the mount, the mount having a mount aperture from the contact surface through to opposite of the contact surface, the mount aperture aligning with the switch aperture when the body is coupled to the mount;
a tamper detector extending through the mount aperture from the contact surface to the mount switch in the body when the body and mount are coupled to each other.

2. The EAS device of claim 1, wherein the tamper detector comprises:
a shaft having a first end and second end, the first end extending to the mount switch in the body and the second end extending to proximal of the contact surface; and,
a floater positioned at the second end of the shaft.

3. The EAS device of claim 1, further comprising:
a locking mechanism in the body, wherein when the body and mount are assembled, the locking mechanism keeps the body and mount from decoupling from each other.

4. The EAS device of claim 3, wherein:
the electronics in the body further comprise a lock switch monitoring the locking mechanism.

5. The EAS device of claim 3, wherein:
the locking mechanism is magnetically releasable by external application of a magnet to the body.

6. The EAS device of claim 1, wherein:
the first coupler of the body comprises the switch aperture; and,
the second coupler of the mount comprises a stem extending from the base, the stem having a fixed end attached to the base and a free end for insertion into the switch aperture, the mount aperture passing from the contact surface to the free end;
the switch aperture and the stem being configured such that when the free end of the stem is inserted into the switch aperture and the body and mount are turned about the stem with respect to each other, the body is coupled to the mount.

7. The EAS device of claim 1, wherein:
the electronics further comprise a microprocessor, wireless communication elements, and an onboard power supply, the microprocessor monitoring the status of the mount switch.

8. The EAS device of claim 1, wherein:
the electronics further comprise a passive EAS element.

9. An electronic article surveillance (EAS) device comprising:
a body housing electronics, the body having a bottom with a coupler aperture through the bottom;
a mount having a base and a stem, the base having a contact surface that is adhesive and the stem extending from the base opposite of the contact surface, the stem having a fixed end attached to the base and a free end for insertion into the coupler aperture, the coupler aperture and the stem being configured such that when the free end of the stem is inserted into the coupler aperture and the body and mount are turned about the stem with respect to each other, the body is coupled to the mount.

10. The EAS device of claim 9, further comprising:
a locking mechanism in the body, wherein when the body and mount are assembled, the locking mechanism keeps the body and mount from decoupling from each other.

11. The EAS device of claim 10, wherein:
the locking mechanism is magnetically releasable by the external application of a magnet to the body.

12. The EAS device of claim 10, wherein:
the stem has a tab extending laterally from its free end;
the coupler aperture has a notch in the perimeter of the coupler aperture, the notch sized to the tab of the stem; and,
the locking mechanism engages the tab to prevent the body and mount from turning with respect to each other.

13. The EAS device of claim 9, further comprising:
a mount switch among the electronics within the body, the mount switch aligning with the coupler aperture in the bottom of the body;
a mount aperture through the mount from the contact surface through the stem to the free end of the stem; and,
a tamper detector extending through the mount aperture from the contact surface to the mount switch in the body when the body and mount are coupled to each other.

14. The EAS device of claim 13, wherein the tamper detector comprises:
a shaft having a first end and second end, the first end extending to the mount switch in the body and the second end extending to proximal of the contact surface; and,
a floater positioned at the second end of the shaft.

15. The EAS device of claim 9, wherein:
the electronics comprise a microprocessor, wireless communication elements, and an onboard power supply.

16. An electronic article surveillance (EAS) device comprising:
a body housing electronics, the body having a bottom with a first coupler;
a mount having a base having a contact surface and a second coupler opposite of the contact surface, the first coupler of the body and the second coupler of the mount being complementarily configured to allow the body to be coupled to the mount; and,
an adhesive element located between the contact surface of the mount and the surface of an item to be protected; wherein,
the base of the mount is flexible and the contact surface of the base conforms to the surface of the item to be protected.

17. The EAS device of claim 16, wherein:
the body has a switch aperture through the bottom, and the electronics comprise a mount switch aligned with the switch aperture;
the mount having a mount aperture from the contact surface through to opposite of the contact surface, the mount aperture aligning with the switch aperture when the body is coupled to the mount; and,
the EAS device further comprising a tamper detector extending through the mount aperture from the contact surface to the mount switch in the body when the body and mount are coupled to each other.

18. The EAS device of claim 17, wherein:
the tamper detector comprises,
a shaft having a first end and second end, the first end extending to the mount switch in the body and the second end extending to proximal of the contact surface, and
a floater positioned at the second end of the shaft.

19. The EAS device of claim 17, wherein:
the first coupler of the body comprises the switch aperture; and,
the second coupler of the mount comprises a stem extending from the base, the stem having a fixed end attached to the base and a free end for insertion into the switch aperture, the mount aperture passing from the contact surface to the free end;
the switch aperture and the stem being configured such that when the free end of the stem is inserted into the switch aperture and the body and mount are turned about the stem with respect to each other, the body is coupled to the mount.

20. The EAS device of claim 16, wherein:
the electronics comprise a microprocessor, wireless communication elements, and an onboard power supply.
